(19) United States
(12) Patent Application Publication
(10) Pub. No.: US 2021/0036247 A1
(43) Pub. Date: Feb. 4, 2021

(54) STACK PATTERNING

(71) Applicant: Flexenable Limited, Cambridge (GB)

(72) Inventors: Josephine Socratous, Cambridge (GB); Neil Murton, Cambridge (GB); Herve Vandekerckhove, Cambridge (GB)

(21) Appl. No.: 16/941,749

(22) Filed: Jul. 29, 2020

(30) Foreign Application Priority Data
Jul. 31, 2019 (GB) 1910884.4

(51) Int. Cl. H01L 51/05

(52) U.S. Cl. CPC H01L 51/052; H01L 51/055

(57) ABSTRACT

A technique of forming a stack of layers defining electrical circuitry and comprising a plurality of inorganic conductor levels, wherein the method comprises: forming a conductor for at least one of the conductor levels in stages before and after a step of patterning an underlying organic layer.

### CLAIM OF PRIORITY

This application claims priority to Great Britain Patent Application No. 1910884.4, filed Jul. 31, 2019, the contents of which is hereby incorporated by reference in their entirety.

### FIELD OF THE INVENTION

Electrical circuitry for e.g., a flat or curved thin-form panel device may be defined by a stack of layers formed in situ on a support substrate.

The use of organic materials such as organic polymer materials for one or more layers can facilitate the use of relatively low-cost production techniques. Cross-linked polymer materials (having giant three-dimensional networks insoluble in any solvent) have been favoured for organic layers to be patterned by dry-etching using a temporary organic patterning mask deposited from solution onto the layer to be patterned.

The inventors for the present application have identified advantages with using non-cross-linked polymer materials, and have developed a technique to facilitate the use of non-cross-linked polymer materials, while avoiding the problems that would favour the use of cross-linked materials.

There is hereby provided a method of forming a stack of layers defining electrical circuitry and comprising a plurality of inorganic conductor levels, wherein the method comprises: forming a conductor for at least one of the conductor levels in stages before and after a step of patterning an underlying organic layer.

According to one embodiment, the method comprises: between two stages of forming the conductor, using the conductor as a mask to pattern the underlying organic layer.

According to one embodiment: one stage of forming the conductor comprises forming a conductor pattern that provides a mask for creating via-holes through the underlying organic layer in one or more interconnect regions at which the conductor is to contact another conductor at a lower conductor level; and another stage of forming the conductor comprises depositing conductor material at least in the region of the via-holes.

According to one embodiment: patterning the underlying organic layer comprises depositing a solution of organic photoresist material; and one stage of forming the conductor before patterning the underlying organic layer comprises forming a layer of inorganic conductor material in all areas in which the solution of organic photoresist material is to be deposited.

According to one embodiment: the conductor comprises a gate conductor pattern for a transistor array, and the underlying organic layer comprises an organic polymer dielectric layer.

According to one embodiment: the underlying organic layer comprises a non-cross-linked polymer layer.

According to one embodiment: the conductor pattern and the conductor material have substantially the same composition.

According to one embodiment: the conductor pattern and the conductor material have different compositions.

According to one embodiment: depositing the conductor material comprises depositing a sub-stack of conductor sub-layers; and/or the conductor pattern comprises a sub-stack of conductor sub-layers.

### BRIEF DESCRIPTION OF THE FIGURES

An embodiment of the present invention is described in detail hereunder, by way of example only, with reference to the accompanying drawings, in which:

FIG. 1 schematically illustrates different areas of an example device; and

FIGS. 2-9 illustrate the processing of a workpiece according to an example embodiment of the present invention, to produce the example device of FIG. 1.

### DETAILED DESCRIPTION

In one example embodiment, the technique is used for the production of an organic liquid crystal display (OLCD) device, which comprises an organic transistor device (such as an organic thin film transistor (OTFT) device) for the control component. OTFTs comprise an organic semiconductor (such as e.g., an organic polymer or small-molecule semiconductor) for the semiconductor channels.

An example of a technique according to an embodiment of the invention is described below for the example of a device comprising a top-gate array of thin-film-transistors (TFTs) for e.g., independently addressing each pixel electrode of an array of pixel electrodes for a display or sensor device. However, the technique is also applicable to other devices.

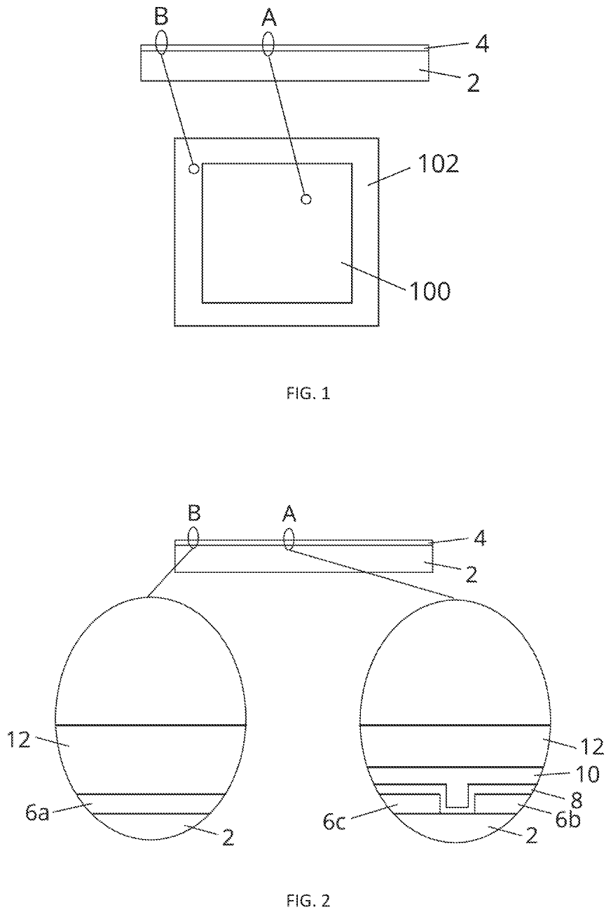

With reference to FIG. 1, an example device comprises an active area 100 occupied by an array of pixel electrodes in the finished device, and an outer area 102 outside the outermost pixel electrodes of the array of pixel electrodes, and occupied by routing/addressing conductors via which each pixel electrode is independently addressable. For example, the routing/addressing conductors may terminate in a fine-pitch array of conductors for bonding to a corresponding fine-pitch array of conductors on a chip-on-flex (COF) component comprising one or more drive chips.

In this example, the final form of a stack of layers formed in situ on a support substrate (e.g., plastics film component comprising a thin plastics support film) includes a plurality of inorganic metallic conductor patterns at different conductor levels of the stack. One conductor pattern at a lower conductor level defines (i) an array of source conductors, each source conductor providing the source electrodes for a respective row of TFTs, and extending to outer area 102, (ii) an array of drain conductors, each providing the drain electrode for a respective TFT and in physical contact with a respective pixel electrode through an interlayer via-hole; and (iii) an array of gate routing conductors each in contact with a respective gate conductor (discussed below) through a respective interlayer via-hole. Another conductor pattern at a higher conductor level in the stack provides an array of gate conductors (gate lines), each providing the gate electrodes for a respective column of TFTs and extending to outer area 102. The terms “row” and “column” are used here as relative terms indicating substantially orthogonal directions, and do not indicate any absolute directions. Each TFT (and therefore each pixel electrode) is associated with a respectively unique combination of source and gate conductors, whereby each pixel electrode is independently addressable via conductors in outer area 102.

The term source conductor is used to indicate a conductor connected in series between the semiconductor channels of the TFTs it serves and the outer area 102; and the term drain conductor is used to indicate a conductor that is connected in series to a source conductor via the semiconductor channel of the respective TFT.

With reference to FIG. 2, the description of a technique according to an example embodiment of the invention begins with a workpiece comprising an intermediate stack of layers 4 formed in situ on a support substrate 2 (e.g., plastics film component comprising at least a plastics support film). The intermediate stack of layers 4 comprises a first conductor pattern defining at least the above-mentioned source conductors 6c, drain conductors 6b and gate routing conductors 6a. In this example, the first conductor pattern 6 comprises metallic silver or a silver alloy.

A patterned organic polymer semiconductor layer 8 defines semiconductor islands each providing the semiconductor channel for a respective TFT. A patterned organic polymer interface dielectric layer 10 provides the semiconductor-dielectric interface of the TFTs. In this example, the patterning of the organic polymer semiconductor layer 8 is done through the organic polymer interface dielectric layer 10, such that the organic polymer semiconductor and the polymer interface dielectric layer have the same pattern.

A layer of non-cross-linked organic polymer dielectric material 12 extends continuously over the active and outer areas 100, 102. In this example, this layer of organic polymer dielectric material 12 is formed by depositing (e.g., spin coating) a solution of the organic polymer dielectric material (which solution does not include any cross-linking agent) onto the upper surface of the workpiece; and the layer of organic polymer dielectric material defines a substantially planar upper surface of the workpiece at this stage.

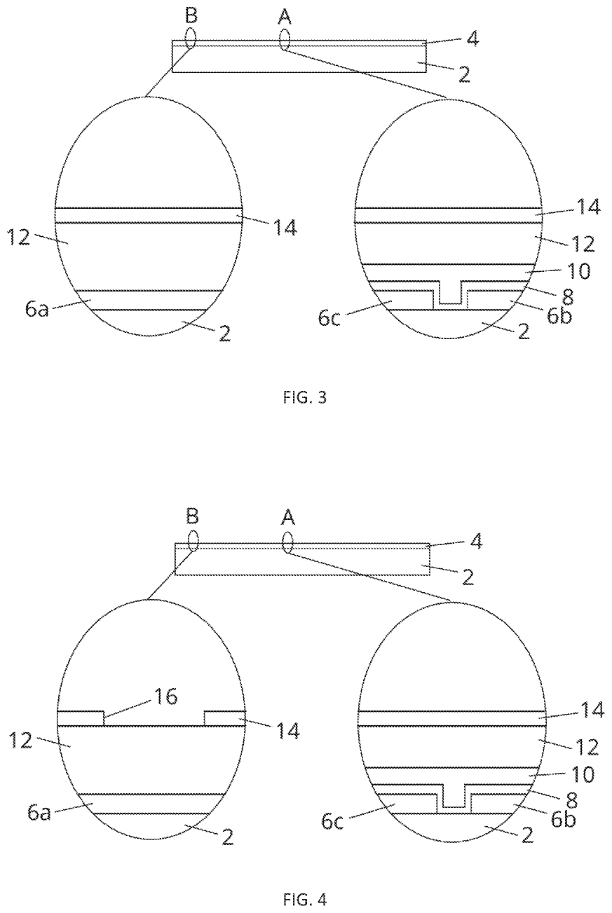

With reference to FIG. 3, a first gate conductor sub-layer (or a first sub-stack of gate conductor sub-layers) 14 is formed in situ on the upper surface of the workpiece, in contact with the soluble polymer dielectric 12. In this example, the thickness of the first gate conductor sub-layer/sub-stack is about 20-100 nm. In this example, the first gate conductor sub-layer(s) is a single inorganic metallic layer (gold) formed by a vapour deposition technique such as sputtering. In this example, this gate conductor sub-layer/sub-stack 14 is formed at this relatively early stage (before patterning of the polymer dielectric layer 12) in order to provide the additional function of serving as a layer of patterning mask material for the step of patterning the organic polymer dielectric layer 12.

With reference to FIG. 4, the first gate conductor sub-layer/sub-stack 14 is patterned to expose the polymer dielectric layer 12 in the regions in outer area 102 at which the gate conductors mentioned above are to contact the gate routing conductors 6a at a lower conductor level. This patterning of the first gate conductor sub-layer/sub-stack 14 may, for example, be done (a) by a laser ablation technique without using any mask formed in situ on the workpiece surface, or (b) by a photolithographical technique comprising (i) depositing a solution of organic photoresist material over the upper surface of the workpiece, (ii) patterning the dried layer of photoresist material, (iii) using the patterned photoresist layer as a mask for wet-etching the first gate conductor sub-layer/sub-stack 14, and (iv) thereafter removing the remaining patterned photoresist layer. Whichever patterning technique is used, the polymer dielectric layer 12 is not exposed to the organic solvent(s) in a solution of organic photoresist material.

With reference to FIG. 5, the patterned first gate conductor sub-layer/sub-stack 14 is then used as a mask for dry-etching of the polymer dielectric layer 12 down to the lower conductor pattern 6, to define via-holes 18 in the regions in which the gate conductors are to contact the gate routing conductors 6a at the lower conductor level.

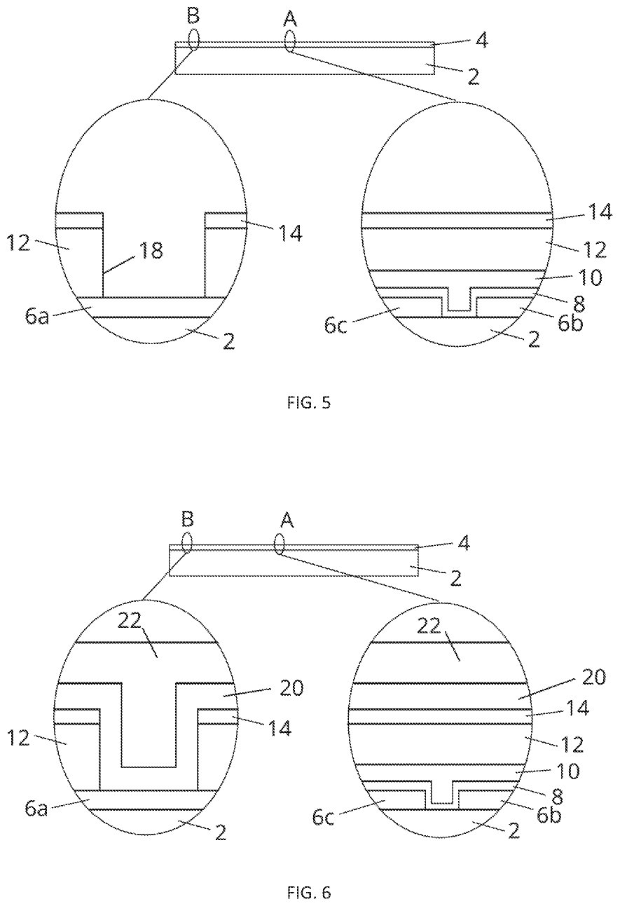

With reference to FIG. 6, a second gate conductor sub-layer (or second sub-stack of gate conductor sub-layers) 20 is formed in situ on the upper surface of the workpiece. In this example, the thickness of the second gate conductor sub-layer/sub-stack is greater than the thickness of the first gate conductor sub-layer/sub-stack and is about 50-200 nm. In this example, the second gate conductor sub-layer has the same composition as the first gate conductor su-layer—they are both noble metal (gold) layers. The second gate conductor sub-layer/sub-stack 20 may, for example, be formed by a vapour deposition technique such as sputtering. The second gate conductor sub-layer/sub-stack 20 contacts the gate routing conductors 6a at the lower level through the interlayer via-holes formed in the polymer dielectric layer 12.

A solution of organic photoresist material is then deposited onto the upper surface of the workpiece, and dried to form a photoresist layer 22 in contact with the upper surface of the second gate conductor sub-layer/sub-stack 20.

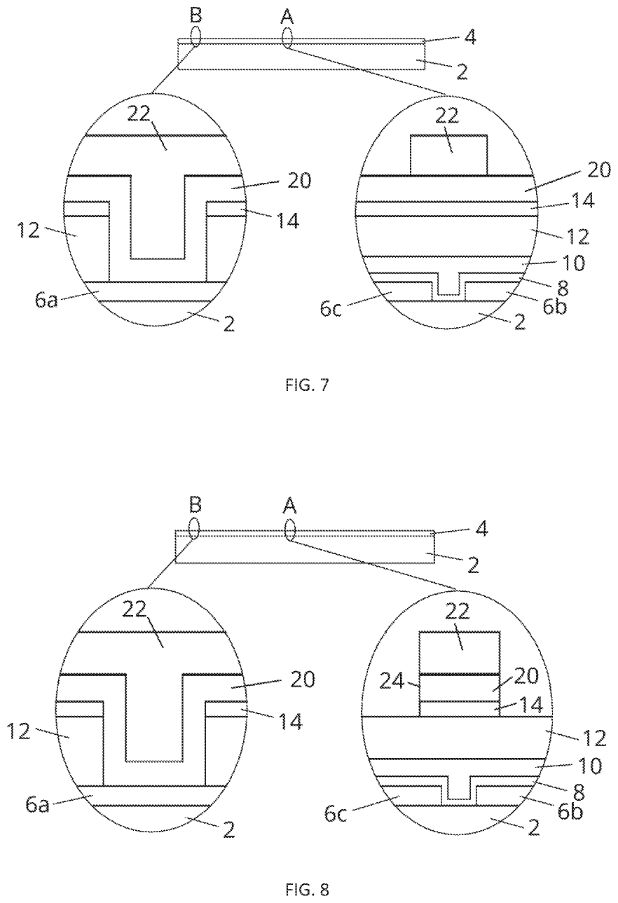

With reference to FIG. 7, a radiation image (negative or positive depending on the kind of organic photoresist material used) of the pattern desired for the gate conductor pattern is then projected onto the photoresist layer 22 using radiation that induces a change in the solubility of the photoresist material. The resulting latent solubility pattern is developed to form a physical pattern in the photoresist layer 22.

With reference to FIG. 8, wet etching is used to pattern the first and second gate conductor sub-layers, using the patterned photoresist layer 22 as an etching mask. In this example, this wet etching uses an acidic etchant, comprising nitric acid and phosphoric acid. This wet etching process forms the gate conductor pattern 24, which defines at least the above-mentioned array of gate conductors (gate lines) 20a, each gate conductor contacting a respective gate routing conductor 6a at the conductor lower level through a respective via-hole in the outer area 102.

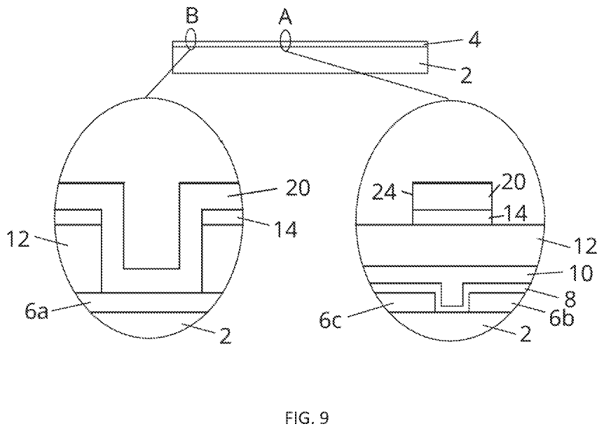

With reference to FIG. 9, the remains of the patterned photoresist layer 22 are then removed.

Not shown in the drawings is further processing of the workpiece, including: forming an organic insulation layer in situ on the upper surface of the workpiece; patterning the organic insulation layer and polymer dielectric layer 12 to form via-holes extending down to each drain conductor 6b; and thereafter forming a top conductor pattern in situ on the upper surface of the workpiece, which top conductor pattern defines an array of pixel electrodes, each pixel electrode in contact with a respective drain conductor through a respective via-hole.

As mentioned above, the above-described technique facilitates the use of non-cross-linked polymer materials for polymer dielectric layer 12. One advantage of not using a cross-linked polymer material for polymer dielectric layer 12 is an observed reduction in deterioration of the lower source-drain conductor pattern 6, as a side-effect of etching the gate conductor layer using an acidic etchant. Without wishing to be bound by theory, the inventors for the present application ascribe this observed deterioration of the source-drain conductor pattern to cross-linking groups (such as acrylate groups) in the cross-linking agent included in the solution of the polymer material for the polymer dielectric layer 12. These cross-linking groups are thought to create a bridge for one or more components of the acid etchant to diffuse down to the source-drain conductor pattern 6 (without the acid etchant etching the polymer dielectric layer 12).

The formation of a gate conductor layer from a stack of inorganic metallic sub-layers in a single processing stage is already used to achieve a conductor pattern with both good conductivity and good adhesion to underlying and overlying organic materials. The above-described technique of dividing the formation of the gate conductor layer into a plurality stages (before and after a step of patterning an underlying gate dielectric) facilitates the use of a wider range of organic dielectric materials for the dielectric layer 12 directly below the gate conductor layer.

In the example described above, the first and second gate conductor sub-layers 14, 20 have substantially the same composition and each consist of a single layer (metallic gold layer). In another example, the first and second gate conductor sub-layers 14, 20 have substantially the same composition but each comprise a sub-stack of sub-layers. For example, both 14, 20 may comprise a sub-stack of molybdenum (Mo), aluminium (Al) and molybdenum (Mo) sub-layers, deposited in that order. In yet another example, the first and second gate conductor sub-layers 14, 20 have different compositions. According to one sub-example, the bottom surface of the first gate conductor sub-layer 14 and the top surface of the second gate conductor sub-layer 20 have substantially the same composition, but the overall composition of the first and second gate conductor sub-layers 14, 20 is different. For example, the first gate conductor sub-layer 14 consists of a single layer of Mo; and the second gate conductor sub-layer 20 comprises a sub-stack of Al and Mo sub-layers deposited in that order. Alternatively, the first gate conductor sub-layer 14 comprises a sub-stack of Mo, Al and Mo layers deposited in that order; and the second gate conductor sub-layer 20 consists of a single layer of Mo.

As mentioned above, an example of a technique according to the present invention has been described in detail above with reference to specific process details, but the technique is more widely applicable within the general teaching of the present application. Additionally, and in accordance with the general teaching of the present invention, a technique according to the present invention may include additional process steps not described above, and/or omit some of the process steps described above.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

What is claimed is:

1. A method of forming a stack of layers defining electrical circuitry and comprising a plurality of inorganic conductor levels, wherein the method comprises:
forming a conductor for at least one of the conductor levels in stages before and after a step of patterning an underlying organic layer.

2. The method according to claim 1, comprising:
between two stages of forming the conductor, using the conductor as a mask to pattern the underlying organic layer.

3. A method according to claim 2:
wherein one stage of forming the conductor comprises forming a conductor pattern that provides a mask for creating via-holes through the underlying organic layer in one or more interconnect regions at which the conductor is to contact another conductor at a lower conductor level; and
wherein another stage of forming the conductor comprises depositing conductor material at least in the region of the via-holes.

4. The method according to claim 1:
wherein patterning the underlying organic layer comprises depositing a solution of organic photoresist material; and
wherein one stage of forming the conductor before patterning the underlying organic layer comprises forming a layer of inorganic conductor material in all areas in which the solution of organic photoresist material is to be deposited.

5. The method according to claim 1:
wherein the conductor comprises a gate conductor pattern for a transistor array, and the underlying organic layer comprises an organic polymer dielectric layer.

6. The method according to claim 1, wherein the underlying organic layer comprises a non-cross-linked polymer layer.

7. The method according to claim 3, wherein the conductor pattern and the conductor material have substantially the same composition.

8. The method according to claim 3, wherein the conductor pattern and the conductor material have different compositions.

9. The method according to claim 3, wherein depositing the conductor material comprises depositing a sub-stack of conductor sub-layers; and/or the conductor pattern comprises a sub-stack of conductor sub-layers.
